(19) United States
(12) Patent Application Publication
(10) Pub. No.: US 2005/0053108 A1
(43) Pub. Date: Mar. 10, 2005

(54) Semiconductor laser device and method for manufacturing the same

(75) Inventor: Takahiro Hashimoto, Yamatokoriyama-shi (JP)

Correspondence Address: Barry E. Bretschneider;Morrison & Foerster LLP, Suite 300, 1650 Tysons Boulevard, McLean, VA, 22102, US

(73) Assignee: Sharp Kabushiki Kaisha, Osaka-shi (JP)

(21) Appl. No.: 10/935,305

(22) Filed: Sep. 8, 2004

(30) Foreign Application Priority Data
Sep. 9, 2003 (JP) 2003-316468

(51) Int. Cl. H01S 5/00

(52) U.S. Cl. 372/46; 372/45

(57) ABSTRACT

A semiconductor laser device has a ridge portion composed of a cladding layer and a cap layer laid on top of the cladding layer, and a filling layer formed on opposite lateral sides of the ridge portion. A top surface of the cap layer and a top surface of the filling layer meet at an angle of 135° or larger but not larger than 180° on an upper side of the cap layer. In manufacturing the device, after a filling layer is formed so as to cover the ridge portion, an insulating film is formed and a portion above the ridge portion is selectively removed from the insulating film to expose the filling layer. Then, the exposed filling layer is removed till a top surface of the ridge portion is exposed.

This nonprovisional application claims priority under 35 U.S.C. §119(a) on Patent Application No(s). 2003-316468 filed in Japan on Sep. 9, 2003, the entire contents of which are hereby incorporated by reference.

### BACKGROUND OF THE INVENTION

The present invention relates to a semiconductor laser device suitable for use in a light source for read access and write access and a manufacturing method therefor, and more particularly, to a semiconductor laser device which is free from strain and offers good device characteristics, and a manufacturing method therefor.

FIG. 4 is a cross sectional view showing a prototype semiconductor laser device manufactured by the inventor of the present invention before the present invention was completed. It should be noted that this semiconductor laser device was disclosed for the first time in the corresponding Japanese Patent Application No. 2003-316468 and has not yet introduced in any other documents.

As shown in FIG. 4, the semiconductor laser device is composed of an N-type buffer layer 102, an N-type cladding layer 103 made of N-type Al_{0.5}Ga_{0.5}As, an active layer 104 made of Al_{0.13}Ga_{0.87}As, a P-type cladding layer 105 made of P-type Al_{0.5}Ga_{0.5}As, a cap layer 106 made of P-type GaAs, and a contact layer 108 made of P-type GaAs, which are stacked in sequence on a substrate 101 made of N-type GaAs. The P-type cladding layer 105 is composed of a first layer formed on the entire surface of the active layer 104 with an almost constant film thickness and a second layer formed on a laterally central portion on the first layer with a mesa shape which constitutes part of a ridge portion 111. The cap layer 106 constitutes the rest of the ridge portion 111.

Moreover, in a portion of the first layer on which the second layer is not formed, there is formed a filling layer 107 made of N-type GaAs in such a manner that the filling layer 107 comes contact with opposite lateral side surfaces of the second layer. The filling layer 107 has two protruding portions which are almost symmetrical with respect to the cap layer 106, in the vicinity of opposite lateral ends of the cap layer 106. The cap layer 106 and respective upper surfaces of the protruding portions meet at an angle smaller than 135° on the upper side of the cap layer.

Moreover, on the top surface of the contact layer 108, a p-type electrode 109 made of Au—Zn is formed, while on the bottom surface of the substrate 101, an N-type electrode 110 made of Au—Ge is formed.

FIGS. 5A to 5I are cross sectional views showing the states of the semiconductor laser device during the manufacturing process. Description will hereinbelow be given of a method for manufacturing the semiconductor laser device with reference to FIGS. 5A to 5I.

First, as shown in FIG. 5A, with use of a MOCVD (Metal-Organic Chemical Vapor Deposition) method, an N-type buffer layer 102, an N-type cladding layer 103, an active layer 104, a P-type cladding layer 105 and a P-type cap layer 106 are stacked in sequence on a wafer-shaped substrate 101 made of N-type GaAs.

Next, both lateral side portions of the P-type cap layer 106 and a part of both across-the-width sides of the P-type cladding layer 105 are etched away to form a ridge portion shown by reference numeral 111 in FIG. 5B. Then, as shown in FIG. 5C, on the top surface of the P-type cladding layer 105 which is not etched away to form the ridge portion 111, a filling layer 112 made of N-type GaAs is grown with use of the MOCVD method so as to surround the cap layer 106 and the ridge portion 111. Thus, growing the filling layer 112 with use of the MOCVD method makes the filling layer 112 grow in conformity with the shape of a plane on which a layer is grown, by which a protruding portion 112a denoted by reference numeral 112a in FIG. 5C is formed in a peripheral part of the cap layer 106 in the filling layer 112.

Next, the filling layer 112 is coated with a photoresist with use of, for example, a spin coat method to form a photoresist film 113 shown in FIG. 5D, and then the photoresist film 113 is irradiated with rays of light for photography such as ultraviolet rays (exposure step). After development, a part of the photoresist film 113 roughly corresponding to the protruding portion 112a is removed as shown in FIG. 5E so that the photoresist film 113 is left only on the opposite lateral sides of the protruding portion 112a.

Next, by using the photoresist film 113 left on both the lateral sides as a mask, the protruding portion 112a shown in FIG. 5E is etched till the cap layer 106 is fully exposed as shown in FIG. 5F, and then the photoresist film 113 is almost completely removed. In this way, the filling layer 107 is formed laterally on the opposite sides of the ridge portion 111 as shown in FIG. 5G, the filling layer 107 having two protruding portions almost symmetrical with respect to the cap layer 106, on the opposite sides of the cap layer 106.

Finally, with use of the MOCVD method, as shown in FIG. 5H, a contact layer 108 is grown on the filling layer 107 and the cap layer 106, and then as shown in FIG. 5I, a p-type electrode 109 made of Au—Zn is formed on the contact layer 108, while an N-type electrode 110 made of Au—Ge is formed on the bottom surface of the substrate 101 to complete a main part of the semiconductor laser device.

However, when removing the resist film portion roughly corresponding to the protruding portion 112a to expose the top surface of the protruding portion 112a, the method for manufacturing the semiconductor laser device utilizes the dispersion or variation in resist coating peculiar to the spin coat method in which the thickness of the resist film in a recess portion tends to increase whereas the thickness of the resist film in a protrusion portion tends to decrease. Therefore, in the case of a negative resist for example, the area of an exposed surface, which is a resist removal area after development, tends to vary depending on the shape of the top surface of the protruding portion, so that the unevenness of the top surfaces of the filling layer and cap layer after etching of the protruding portion 112a tends to vary. That is, running variation, in other words, variation among runs or batches tends to be produced in horn-shaped protruding portions of the filling layer on both the lateral sides of the cap layer.

In most cases, after irradiation of the photoresist and pattern development, the N-type GaAs layer is exposed only at the top surface 112b of the protruding portion 112a, and the other portions, though decreased, are left as a mask. This brings about a problem that after etching of the protruding portion 112a, as shown in FIG. 5G, protruding portions 112c are generated in the filling layer 112 on the opposite lateral sides of the cap layer, each of the protruding portions 112c having an angle of inclination with respect to the top surface of the cap layer 106 that is smaller than 135° on the upper side of the cap layer 106 and having a horn shape corresponding to the shape of the protruding portion 112a before etching.

Because of the above, there is a problem that strain is generated to a surface having the protruding portions 112c, that is, for example, to the contact layer 108 formed by the MOCVD method. Further, there is still another problem that the strain attributed to forming the contact layer 108 on the protruding portions 112c by the MOCVD method is exerted not only to the contact layer 108 but also to the N-type cladding layer 103 and the substrate 101, which results in negative influence on a light-emitting region of the active layer 104, and deteriorate the light-emitting characteristics of the semiconductor laser device.

### SUMMARY OF THE INVENTION

Accordingly, an object of the present invention is to provide a semiconductor laser device which is free from a noticeable protruding portion on a top surface of a filling layer so as to achieve decreased strain and offer good device characteristics, and to provide a manufacturing method therefor.

In order to accomplish the above object, a semiconductor laser device according to an aspect of the present invention includes:
a ridge portion composed of a cladding layer and a cap layer laid on top of the cladding layer; and
a filling layer formed on opposite lateral sides of the ridge portion, wherein a top surface of the cap layer and a top surface of the filling layer meet at an angle of 135° or larger but not larger than 180° on an upper side of the cap layer.

The filling layer normally includes an opposite conductivity layer having a conductivity type opposite to the conductivity type of the ridge portion, or a high-resistance layer.

According to the semiconductor laser device of the invention, the top surface of the cap layer and the top surface of the filling layer meet (contact) at an angle of 135° or larger but not larger than 180°, which angle is larger than that of the semiconductor laser device shown in FIG. 4, on the upper side of the cap layer, so that a junction portion between the top surface of the cap layer and the top surface of the filling layer takes an almost planar form, and therefore a layer such as a contact layer can be formed on the top surface of the cap layer and the top surface of the filling layer which have the almost planar junction portion. This makes it possible to considerably decrease a degree of strain generated on the layer such as the contact layer, which in turn allows considerable decrease in the degree of strain not only in the layer such as the contact layer but also in the cladding layer, the substrate or the like. Therefore, it becomes possible to improve durability of the semiconductor laser device in the present invention as well as its device characteristics such as oscillation intensity.

In one embodiment, there are two said ridge portions, and these two ridge portions are electrically insulated from each other.

The semiconductor laser device in this embodiment can emit laser light beams with two wavelengths and can be used as, for example, a so-called monolithic-type dual-wavelength semiconductor laser device capable of reproducing DVDs and CDs. In this semiconductor laser device, the top surface of each cap layer and the top surface of the associated filling layer meet at an angle of 135° or larger but not larger than 180° on the upper side of the cap layers, so that a layer such as a contact layer can be formed on the almost planar top surfaces of the cap layers and filling layers. This makes it possible to considerably decrease the degree of strain generated in layers such as the contact layer, which in turn allows considerable decrease in the degree of strain not only in the layers such as the respective contact layers but also in the respective cladding layers, substrate or the like, allowing improvement of the durability of the monolithic-type dual-wavelength semiconductor laser device as well as its device characteristics.

According to one embodiment, a contact layer or the like is formed on top of the filling layer(s) and the cap layer(s), making it possible to reduce a contact resistance between the filling layer(s) and cap layer(s) and an electrode(s) formed on the layer(s) such as the contact layer(s).

Also, a method for manufacturing a semiconductor laser device according to another aspect of the present invention includes:
a step of stacking a plurality of films including a cladding layer and a cap layer on a substrate;
a ridge portion forming step of forming a ridge portion by removing a part of the cladding layer and a part of the cap layer;
a filling layer forming step of forming a filling layer composed of a lateral portion that is in contact with a lateral surface of the ridge portion, and a protruding portion covering the cap layer;
an insulating layer forming step of forming an insulating layer on an upper surface of the filling layer;
a resist coating step of coating an upper surface of the insulating layer with a resist;
a resist removing step of removing a portion of the resist roughly corresponding to a top surface of the protruding portion;
a first insulating layer removing step of, after the resist removing step, removing a portion of the insulating layer roughly corresponding to the top surface of the protruding portion with the remaining resist as a mask to thereby expose the top surface of the protruding portion;
a second insulating layer removing step of, after the first insulating layer removing step, further removing at least a part of an insulating layer portion between the remaining resist and the protruding portion; and
a protruding portion removing step of, after the second insulating layer removing step, removing the protruding portion of the filling layer with the remaining insulating layer as a mask till a top surface of the cap layer is exposed.

According to the method for manufacturing a semiconductor laser device of the present invention, the top surface of the protruding portion of the filling layer is exposed in the first insulating layer removing step, and further, in the second insulating layer removing step, an etchant is deliberately infiltrated into the insulating layer below the resist on the opposite sides of the top surface of the protruding portion to conduct side etching. Adjusting the degree of this side etching makes it possible to adjust a superficial area of a mask portion when the protruding portion removing step is carried out. This makes it possible to adjust an angle formed on the upper side of the cap layer between the top surface of the filling layer and the top surface of the cap layer after the protruding portion removing step to be 135° or larger but not larger than 180°, allowing manufacturing of the semiconductor laser device with decreased strain and good device characteristics.

In one embodiment, the method for manufacturing a semiconductor laser device further includes an etching time determining step of, between the first insulating layer removing step and the second insulating layer removing step, examining an exposed portion of the filling layer exposed by the first insulating layer removing step and measuring an area of the exposed portion to determine etching time for the second insulating layer removing step.

According to the method in this embodiment, even if dispersion or variation is found in the shape of the protruding portion, the dispersion can be compensated, enabling the angle to be formed on the upper side of the cap layer between the top surface of the filling layer and the top surface of the cap layer to approximate 180°.

According to one embodiment of the method for manufacturing a semiconductor laser device, the insulating layer is composed of a SiO₂ layer, which is an ordinary layer having a tolerance to an etchant of GaAs crystals. Therefore, the insulating layer can be formed easily, and in the case of forming the filling layer from GaAs, a remaining insulating layer can be maintained in a good state during the protruding portion removing step.

In one embodiment of the method for manufacturing a semiconductor laser device, the insulating layer forming step is carried out with use of a plasma CVD method.

According to the method for manufacturing semiconductor laser devices in this embodiment, an insulating layer can be formed on the filling layer with coverage better than in the case of forming the insulating layer on the filling layer with use of a vapor deposition method or a spatter method.

In one embodiment of the method for manufacturing a semiconductor laser device, as the substrate, a substrate having a growth face inclined from a {100} facet is used.

In some applications of semiconductor lasers, a growth surface of a substrate to be used should preferably be inclined from the {100} facet. In the case in which the growth face of the substrate is inclined from the {100} facet or plane, it is known that after the protruding portion of the filling layer is etched, there is produced a protruding portion which has an almost right angle of inclination and is in horn-shaped.

However, according to the method for manufacturing a semiconductor laser device in the above embodiment, even in the case where the growth face of the substrate is inclined from the {100} facet, no protruding portion of the filling layer that has an almost right angle of inclination and is in horn-shaped would be produced in the vicinity of the opposite ends of the cap portion after the protruding portion of the filling layer is removed by etching, thereby making it possible to manufacture semiconductor laser devices with good device characteristics.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a cross sectional view showing the structure of a semiconductor laser device in one embodiment of the present invention;

FIGS. 2A to 2M are cross sectional views of the semiconductor laser device in the above embodiment in manufacturing process steps;

FIG. 3 is a cross sectional view showing the structure of a semiconductor laser device in another embodiment of the present invention;

FIG. 4 is a cross sectional view showing the structure of a semiconductor laser device in the background art; and

FIGS. 5A to 5I are cross sectional views showing the background art semiconductor laser device in the manufacturing process.

### DETAILED DESCRIPTION OF THE PREFERRED EMBODIMENTS

Hereinbelow, the present invention will be described in detail in conjunction with the preferred embodiments with reference to the accompanying drawings.

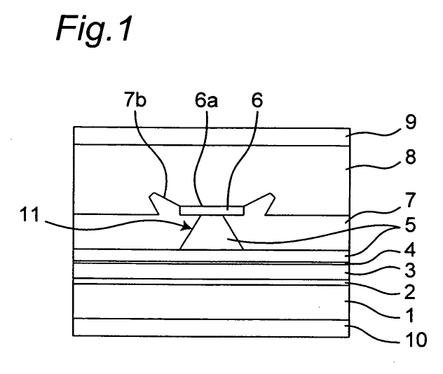

FIG. 1 is a cross sectional view showing the structure of a semiconductor laser device in one embodiment of the present invention.

As shown in FIG. 1, a semiconductor laser device of the present embodiment has an N-type buffer layer 2, an N-type cladding layer 3 made of N-type Al_{0.5}Ga_{0.5}As, an active layer 4 made of Al_{0.13}Ga_{0.87}As, a P-type cladding layer 5 made of P-type Al_{0.5}Ga_{0.5}As and a cap layer 6 made of P-type GaAs which layers constitute a ridge portion 11, a filling layer 7 made of N-type GaAs and formed on opposite lateral sides of the ridge portion 11 of the P-type cladding layer 5, and a contact layer 8 made of P-type GaAs, all of which layers are stacked in sequence on a substrate 1 made of N-type GaAs having a growth face inclined from the {100} facet. A top surface 6a of the cap layer 6 and a top surface 7b of the filling layer 7 adjacent to the top surface 6a meet (contact) at an angle of 135° or larger but not larger than 180° on the upper side of the cap layer 6. Moreover, on a top surface of the contact layer 8, a P-type electrode 9 made of Au—Zn is formed, while on the bottom surface of the substrate 1, an N-type electrode 10 made of Au—Ge is formed.

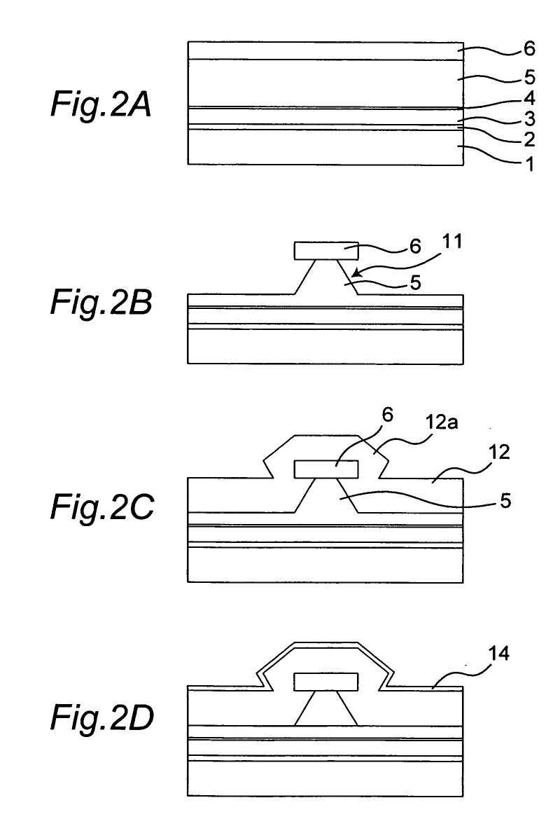

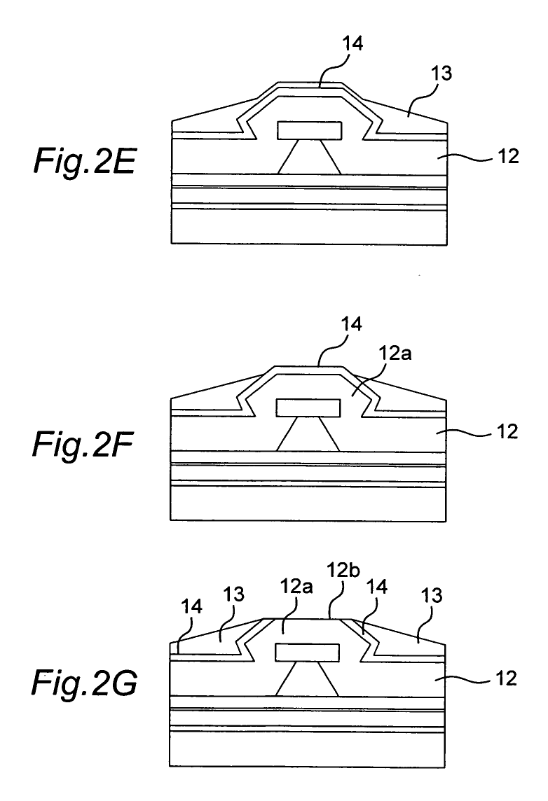

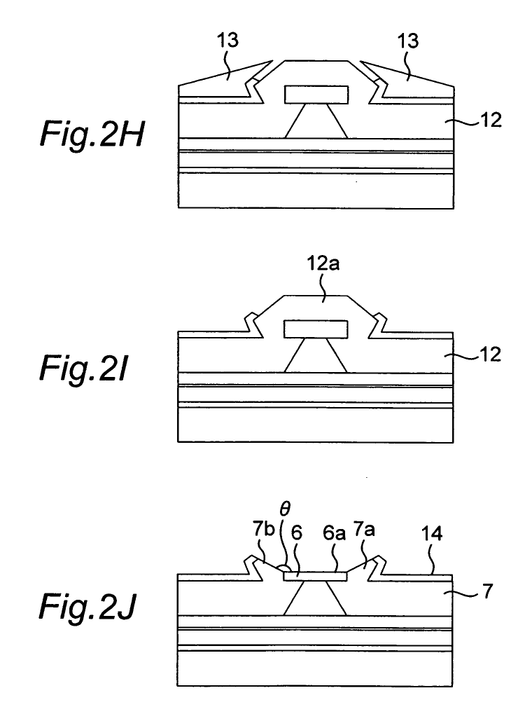

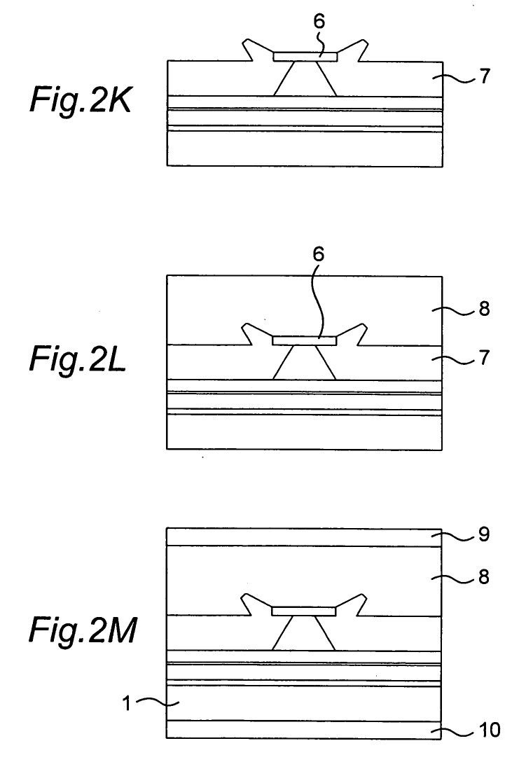

FIGS. 2A to 2M are cross sectional views showing the states of the semiconductor laser device of the embodiment during the manufacturing process.

Description will hereinbelow be given of a method for manufacturing the semiconductor laser device in the embodiment with reference to FIGS. 2A to 2M.

First, as shown in FIG. 2A, with use of the MOCVD method, an N-type buffer layer 2, an N-type cladding layer 3, an active layer 4, a P-type cladding layer 5 and a P-type cap layer 6 are stacked in sequence on a wafer-shaped substrate 1 made of N-type GaAs having a growth face inclined relative to the {100} facet.

Next, a ridge portion forming step is carried out. In the ridge portion forming step, as shown in FIG. 2B, the entire portions of opposite lateral sides of the P-type cap layer 6 and a specified depth portion of the opposite lateral side portions of the P-type cladding layer 5 roughly corresponding to the opposite lateral side portions of the P-type cap layer 6 are removed by etching to form a ridge portion denoted by reference numeral 11 in FIG. 2B.

Next, a filling layer forming step is carried out. In the filling layer forming step, a filling layer 12 as shown in FIG. 2C is grown on the P-type cladding layer 5 and the P-type cap layer 6 by the MOCVD method, the filling layer 12 being composed of lateral portions that are in contact with the lateral surfaces of the cladding layer 5 part in the ridge portion 11 and a protruding portion 12a covering the lateral surfaces and the top surface of the P-type cap layer 6 in the shape roughly corresponding to the outer shape of the P-type cap layer 6, and which is made of N-type GaAs. It is to be noted that in the case where the filling layer 12 is grown by the MOCVD method as shown in this embodiment, the filling layer 12 is grown into a shape in conformity with the shape of a surface on which the filling layer 12 is grown, so that the protruding portion 12a which protrudes toward the opposite lateral sides of the cap layer 6 is naturally produced in conformity with the shape of the ridge portion 11.

Next, an insulating layer forming step is carried out. In the insulating layer forming step, an insulating layer 14 made of a SiO₂ dielectric layer is formed on the filling layer 12 with use of a plasma CVD method, which offers better coverage than a vapor deposition method or a spatter method, as shown in FIG. 2D. SiN and A1₂O₃ may also be used as materials of the insulating layer 14.

Next, a resist coating step is carried out. In the resist coating step, the insulating layer 14 is coated with a positive resist with use of, for example, a spin coat method to form a photoresist film 13, as shown in FIG. 2E.

Next, a resist removing step is carried out. In the resist removing step, the photoresist film 13 is irradiated with (exposed to) rays of light for photography such as ultraviolet rays. After development, a portion of the photoresist film 13 roughly corresponding to the top surface of the protruding portion 12a is removed, as shown in FIG. 2F.

Next, a first insulating layer removing step is carried out. In the first insulating layer removing step, after the resist removing step, with the photoresist film 13 remaining on the opposite lateral sides of the protruding portion 12a as a mask, a portion of the insulating layer 14 roughly corresponding to the top surface of the protruding portion 12a is removed to temporarily expose a top surface of the protruding portion 12a, as shown in FIG. 2G.

Next, an etching time determining step is carried out. In this etching time determining step, an edge of the wafer is cut off so that a cross section of the protruding portion is visually checked in the state that the top surface of the protruding portion 12a is exposed, and an aperture area of a ridge head portion, that is an exposed area of the filling layer 12, is examined and measured through SEM (Scanning Electron Microscope) observation or the like for determining a time during which an insulating layer 14 portion between the photoresist film 13 and the protruding portion 12a is etched in the following second insulating layer removing step.

Next, the second insulating layer removing step is carried out. In the second insulating layer removing step, etching is performed for the time determined in the etching time determining step to remove a part of the insulating layer 14 portion between the photoresist film 13 and the protruding portion 12a to form the semiconductor laser device under manufacturing process into a shape shown in FIG. 2H. It is to be noted that this additional etching is a side etching performed to deliberately infiltrate an etchant into the insulating layer below the resist on the opposite sides of the exposed portion of the filling layer 12, and therefore that the etching rate is slow and controllable.

Next, a protruding portion removing step is carried out. In this protruding portion removing step, after the remaining photoresist film denoted by reference numeral 13 in FIG. 2H is removed as shown in FIG. 2I, the protruding portion 12a shown in FIG. 2I is etched using the insulating layer 14 subjected to the aforementioned additional etching as a mask till the shape of the filling layer denoted by reference numeral 12 in FIG. 2I turns into the shape denoted by reference numeral 7 in FIG. 2J, i.e., till the top surface 6a of the cap layer 6 is exposed.

Next, as shown in FIG. 2K, after the insulating layer 14 remaining on both sides of the cap layer 6 of FIG. 2J is almost fully separated or removed, a contact layer 8 is formed on the cap layer 6 and the filling layer 7, as shown in FIG. 2L.

Finally, a p-type electrode 9 made of Au—Zn is formed on the contact layer 8, while an N-type electrode 10 made of Au—Ge is formed on the bottom surface of the substrate 1 to complete a main part of the semiconductor laser device shown in FIG. 2M.

It is to be understood that the materials used for the substrate 1, the layers 2 to 8 and the electrodes 9, 10 constituting the semiconductor laser device of the present embodiment are presented only as an example and therefore not limitative, so that use of other materials is accepted.

According to the semiconductor laser device in the embodiment, the top surface of the cap layer 6 and the top surface 7b of the filling layer 7 meet at an angle of 135° or larger but not larger than 180° on the upper side of the cap layer 6, which angle is far larger than that of the semiconductor laser device shown in FIG. 4, so that a junction portion of the top surface 6a of the cap layer 6 and the top surface 7b of the filling layer 7 is in an almost planar state, and therefore the contact layer 8 can be formed on the top surface 6a of the cap layer 6 and the top surface 7b of the filling layer 7 which have the almost planar junction portion. This makes it possible to considerably decrease the degree of strain generated in the contact layer 8, as compared to the semiconductor laser device of FIG. 4, which in turns allows considerable decrease in the degree of stain not only in the contact layer 8 but also in the cladding layer 5, the substrate 1 or the like. Therefore, it becomes possible to improve durability of the semiconductor laser device in the aforementioned embodiment as well as its device characteristics such as oscillation intensity.

Further, according to the semiconductor laser device in the aforementioned embodiment, the uneven surfaces of the filling layer 7 and the cap layer 6 are in an almost planar state, and therefore the unevenness less tends to be reflected on the top surface of the contact layer which will be formed thereafter. As a result, it becomes possible to reduce the thickness of the contact layer, and in the case where the contact layer is used to provide a die bonding face to the electrode 9 which is formed on top thereof, a thermal resistance thereof can be reduced considerably.

Further, according to the method for manufacturing the semiconductor laser device in the above embodiment, a portion of the insulating layer 14 roughly corresponding to the top surface of the protruding portion 12a is removed so as to expose the top surface of the protruding portion 12a of the filling layer 12 in the first insulating layer removing step, and then, in the second insulating layer removing step, an etchant is deliberately infiltrated into the remaining insulating layer 14 below the photoresist film 13 on the opposite sides of the exposed portion to conduct side etching. Accordingly, adjusting the degree of this side etching makes it possible to adjust a superficial area of the insulating layer 14 for use as a mask when the protruding portion removing step is carried out. Consequently, after the protruding portion removing step, a noticeable horn-shaped protruding portion composed of the top surface 7b of the filling layer 7 and the top surface 6a of the cap layer 6 which meet (contact) at an angle of smaller than 135° on the upper side of the cap layer 6 would not be produced on the opposite lateral side portions of the cap layer 6 in the filling layer 7, allowing manufacturing of the semiconductor laser device with decreased strain and good device characteristics.

Further, there is provided an etching time determining step of examining an exposed portion of the filling layer 12 exposed by the first insulating layer removing step and measuring an area of the exposed portion to determine etching time in the second insulating layer removing step. Consequently, even if dispersion, or variation in the shape of the protruding portion 12a is found among semiconductor laser devices, the dispersion can be compensated, enabling the angle between the top surface 7a of the filling layer 7 and the top surface 6a of the cap layer 6 formed on the upper side of the cap layer 6 to approximate 180° after the protruding portion removing step.

Further, the insulating layer 14 is composed of a SiO₂ layer, which is a commonly used layer, thereby allowing facilitated film formation.

Further, the insulating layer forming step is conducted with use of the plasma CVD method, which makes it possible to form the insulating layer 14 on the filling layer 12 with coverage better than that in the case of forming the insulating layer on the filling layer with use of the vapor deposition method or the spatter method.

Further, the method for manufacturing semiconductor laser devices of the present invention is applied to manufacturing a semiconductor laser device with use of the substrate 1 having a growth face inclined from the {100} plane. Consequently, even in the case where the growth face of a substrate 1 used is inclined from the {100} plane like this embodiment, a noticeable horn-shaped protruding portion having an almost right angle of inclination would not be produced in the vicinity of the opposite lateral sides of the cap layer 6 after the protruding portion 12a of the filling layer 12 is etched. This allows manufacturing of the semiconductor laser device with good device characteristics.

In the semiconductor laser device in the aforementioned embodiment, a first layer in the cladding layer 5 which is formed on the entire top surface of the active layer 4 and has an almost constant film thickness, and a mesa-shaped second layer in the cladding layer 5 which is formed on a laterally central portion of a top surface of the first layer and constitutes a part of the ridge portion 11 are structured to be in a contiguous state. However, in the semiconductor laser device of the present invention, the first layer in the cladding layer 5 which is formed on the entire top surface of the active layer and has an almost constant film thickness, and the mesa-shaped second layer in the cladding layer 5 which is formed on the laterally central portion of the surface of the first layer and constitutes a part of the ridge portion may be separated from each other via an etching stop layer.

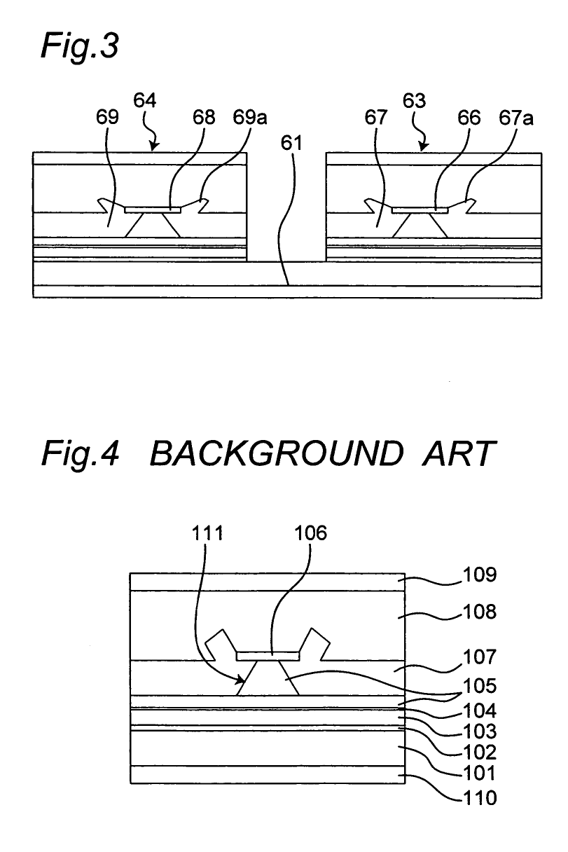

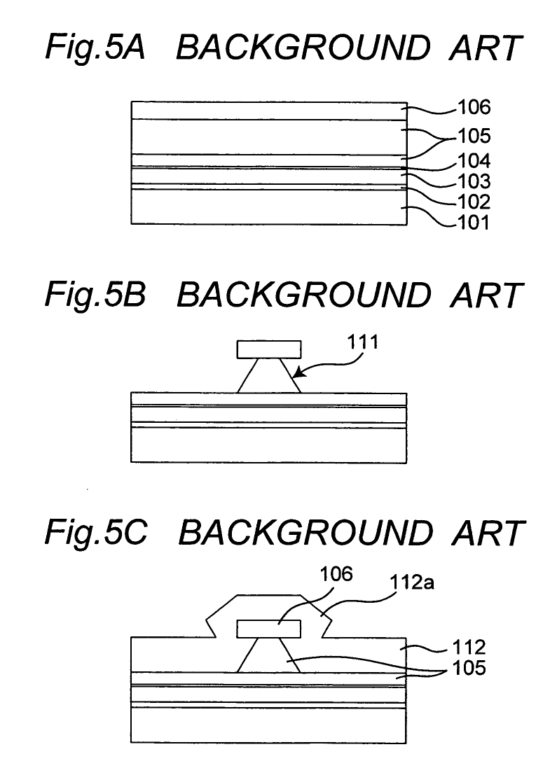

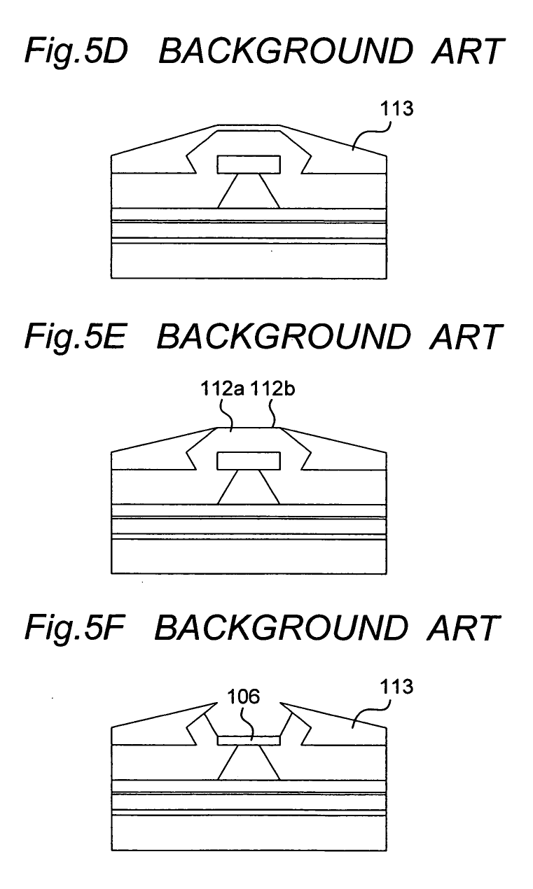

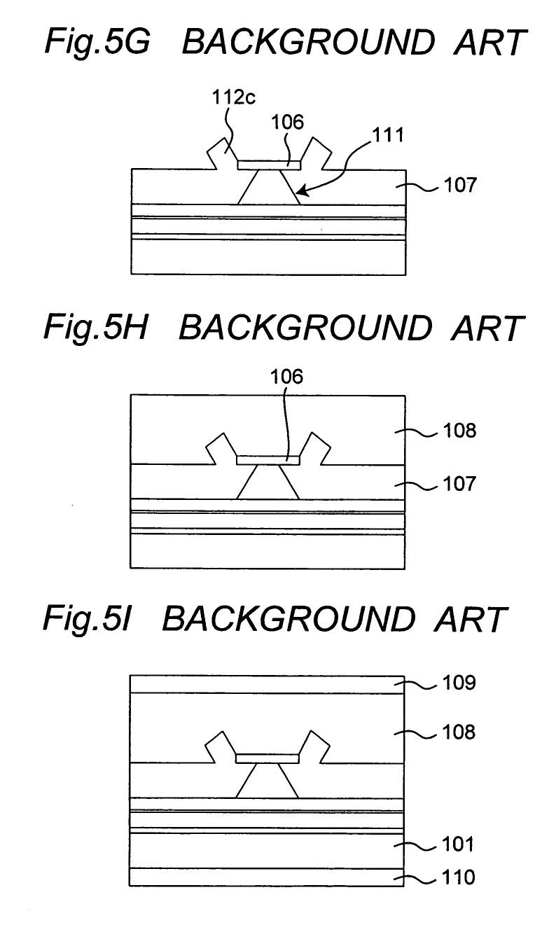

FIG. 3 is a cross sectional view showing a semiconductor laser device in another embodiment of the present invention. The semiconductor laser device is a so-called monolithic-type dual-wavelength semiconductor laser device capable of reproducing both CDs and DVDs, for example. In the monolithic-type dual-wavelength semiconductor laser device, a first semiconductor laser device 63 made of AlGaAs-based materials for emitting laser light beam with a wavelength of 780 nm for CDs is formed on one side of a substrate 61, and a second semiconductor laser device 64 made of AlGaInP-based materials for emitting laser light beam with a wavelength of 650 nm for DVDs is formed on the other side of the substrate 61. Though not shown in the drawing, an isolation portion for electrically insulating the ridge portions from each other is provided between the first semiconductor laser device 63 and the second semiconductor laser device 64.

The first semiconductor laser device 63 and the second semiconductor laser device 64 are manufactured with use of the semiconductor laser manufacturing method which was applied to manufacturing of the semiconductor laser device shown in FIG. 1 and was described with reference to FIGS. 2A to 2M. In manufacturing the semiconductor laser device, steps including the ridge portion forming step, the filling layer forming step, the insulating layer forming step, the resist coating step and the resist removing step, as well as the first insulating layer removing step, the second insulating layer removing step and the protruding portion removing step are simultaneously conducted for the first semiconductor laser device and the second semiconductor laser device.

Therefore, in the monolithic-type dual-wavelength semiconductor laser device in this embodiment, as with the semiconductor laser device shown in FIG. 1, a top surface of a cap layer 66 and a top surface of a protruding portion 67a of a filling layer 67 in the first semiconductor laser device 63 meet at an angle of 135° or larger but not larger than 180° on the upper side of the cap layer 66, and a top surface of a cap layer 68 and a top surface of a protruding portion 69a of a filling layer 69 in the second semiconductor laser device 64 meet at an angle of 135° or larger but not larger than 180° on the upper side of the cap layer 68.

According to the monolithic-type dual-wavelength semiconductor laser device in the embodiment, the top surface of each of the cap layers 66, 68 and the top surface of each of the filling layers 67, 69 in the first and second semiconductor laser devices 63, 64 meet at an angle of 135° or larger but not larger than 180° on the upper side of each of the cap layers 66, 68. Therefore, it becomes possible to form a contact layer having decreased strain and good crystalline structure on the almost planar top surfaces of the cap layers 66, 68 and the top surfaces of the filling layers 67, 69. This allows considerable decrease in the degree of strain not only in the contact layers but also in the cladding layers and the substrates, thereby making it possible to improve durability of the semiconductor laser device in the above embodiment that is a monolithic-type dual-wavelength semiconductor laser device capable of replaying both DVDs and CDs, as well as to improve its device characteristics such as emission intensity of the two laser light beams.

It should be understood that mole fractions in the compositions to be employed for each of layers in the semiconductor laser device of the present invention are not limited to the numerical values specifically described in connection with the above embodiment. It should also be understood that the thickness of each layer in the semiconductor laser device of the present invention is not limited to the numerical values specifically described in connection with the semiconductor laser device in the above embodiment.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor laser device, comprising:
a ridge portion composed of a cladding layer and a cap layer laid on top of the cladding layer; and
a filling layer formed on opposite lateral sides of the ridge portion, wherein
a top surface of the cap layer and a top surface of the filling layer meet at an angle of 135° or larger but not larger than 180° on an upper side of the cap layer.

2. The semiconductor laser device as defined in claim 1, wherein
there are two said ridge portions, and these two ridge portions are electrically insulated from each other.

3. A method for manufacturing a semiconductor laser device, comprising:
a step of stacking a plurality of films including a cladding layer and a cap layer on a substrate;
a ridge portion forming step of forming a ridge portion by removing a part of the cladding layer and a part of the cap layer;
a filling layer forming step of forming a filling layer composed of a lateral portion that is in contact with a lateral surface of the ridge portion, and a protruding portion covering the cap layer;
an insulating layer forming step of forming an insulating layer on an upper surface of the filling layer;
a resist coating step of coating an upper surface of the insulating layer with a resist;
a resist removing step of removing a portion of the resist roughly corresponding to a top surface of the protruding portion;
a first insulating layer removing step of, after the resist removing step, removing a portion of the insulating layer roughly corresponding to the top surface of the protruding portion with the remaining resist as a mask to thereby expose the top surface of the protruding portion;
a second insulating layer removing step of, after the first insulating layer removing step, further removing at least a part of an insulating layer portion between the remaining resist and the protruding portion; and
a protruding portion removing step of, after the second insulating layer removing step, removing the protruding portion of the filling layer with the remaining insulating layer as a mask till a top surface of the cap layer is exposed.

4. The method for manufacturing a semiconductor laser device as defined in claim 3, further comprising:
an etching time determining step of, between the first insulating layer removing step and the second insulating layer removing step, examining an exposed portion of the filling layer exposed by the first insulating layer removing step and measuring an area of the exposed portion to determine etching time for the second insulating layer removing step.

5. The method for manufacturing a semiconductor laser device as defined in claim 3, wherein
the insulating layer is a SiO₂ layer.

6. The method for manufacturing a semiconductor laser device as defined in claim 3, wherein
the insulating layer forming step is carried out with use of a plasma CVD method.

7. The method for manufacturing a semiconductor laser device as defined in claim 3, wherein
a substrate having a growth face inclined from a {100} facet is used as the substrate.

8. A method for manufacturing a semiconductor laser device, comprising:
forming a ridge portion composed of a cladding layer and a cap layer laid on top of the cladding layer;
forming a filling layer so as to cover the ridge portion;
forming an insulating film on the filling layer;
selectively removing a portion positioned above the ridge portion from the insulating film to expose the filling layer; and
removing the exposed filling layer till a top surface of the ridge portion is exposed.
